(19) United States
(12) Patent Application Publication
(10) Pub. No.: US 2025/0107292 A1
(43) Pub. Date: Mar. 27, 2025

(54) METHOD FOR PRODUCING AN OPTOELECTRONIC COMPONENT AND OPTOELECTRONIC COMPONENT

(71) Applicant: AMS-OSRAM INTERNATIONAL GMBH, Regensburg (DE)

(72) Inventors: Markus Klein, Regensburg (DE); Tobias Gebuhr, Bad Abbach (DE); Michael Betz, Bodenkirchen (DE)

(21) Appl. No.: 18/832,418

(22) PCT Filed: Jan. 13, 2023
(86) PCT No.: PCT/EP2023/050754

§ 371 Date: Jul. 23, 2024

(30) Foreign Application Priority Data
Jan. 24, 2022 (DE) 10 2022 101 579.3

(51) Int. Cl. H01L 33/54; H01L 33/50; H01L 33/56; H01L 33/60

(52) U.S. Cl. CPC H10H 20/853; H10H 20/851; H10H 20/854; H10H 20/856; H10H 20/0362; H10H 20/0363

(57) ABSTRACT

In an embodiment a method includes introducing a semiconductor chip and a cover body, arranged on an upper side of the semiconductor chip, into a mold, enclosing the semiconductor chip and the cover body in the mold with a molding compound, wherein side faces of the semiconductor chip, side faces of the cover body, and a top face of the cover body, which faces away from the semiconductor chip, are covered by the molding compound, at least partially curing the molding compound in order to form a molded body, removing the mold and thinning the molded body by a jet/beam process, wherein the molded body is removed from the top face of the cover body, and wherein the molded body has a cavity in a region of the projection after removing the mold.

### CROSS-REFERENCE TO RELATED APPLICATIONS

This patent application is a national phase filing under section 371 of PCT/EP2023/050754, filed Jan. 13, 2023, which claims the priority of German patent application 10 2022 101 579.3, filed Jan. 24, 2022, each of which is incorporated herein by reference in its entirety.

### TECHNICAL FIELD

A method for producing an optoelectronic component and an optoelectronic component are provided.

### SUMMARY

Embodiments provide a method for producing an optoelectronic component, in which constituent parts of the optoelectronic component are mechanically stressed to a particularly low degree during production of the optoelectronic component. Further embodiments provide an optoelectronic component having improved optical properties.

According to at least one embodiment of the method, the method comprises a method step in which a semiconductor chip with a cover body on an upper side of the semiconductor chip is introduced into a mold.

The semiconductor chip is, for example, an optoelectronic semiconductor chip. In particular, the semiconductor chip is a semiconductor chip which is adapted to emit electromagnetic radiation, in particular light, during operation. For example, the semiconductor chip is a light-emitting diode chip.

The cover body is placed on an upper side of the semiconductor chip, and for example fastened thereon. For example, the cover body may be fastened on the semiconductor chip by direct bonding or a bonding agent, for instance an adhesive.

The cover body may be at least partially transmissive for electromagnetic radiation generated during operation in the semiconductor chip. For example, the cover body is one of the following elements or comprises one of the following elements: optical element, glass platelet, optical diffuser, conversion element.

The optical element may, for example, be a lens. The glass platelet may, for example, be a carrier for a converter and/or mechanical protection for the semiconductor chip. The diffuser may, for example, be a roughened platelet or a platelet filled with diffusion particles, for example a glass platelet, which is adapted to scatter the electromagnetic radiation which is generated during operation in the semiconductor chip and which passes through the diffuser. The conversion element is, for example, adapted to absorb at least a part of the electromagnetic radiation which is generated during operation in the semiconductor chip and which enters the conversion element, and to reemit electromagnetic radiation with a different, for example longer, wavelength.

The mold comprises at least one opening, into which the semiconductor chip with the cover body can be introduced. For example, the mold comprises a multiplicity of openings which are arranged laterally next to one another parallel to a main extent plane of the mold, a semiconductor chip with an associated cover body being able to be introduced into each opening. The mold is configured in such a way here that it is not in direct contact with the semiconductor chip and the cover body on the side faces of the semiconductor chip and the side faces of the cover body and on the top face of the cover body which faces away from the semiconductor chip. In other words, there is a spacing between the constituent parts and the mold on the side faces of the semiconductor chip and of the cover body and on the top face of the cover body.

According to at least one embodiment, the method comprises a step in which the semiconductor chip and the cover body in the mold are enclosed with a molding compound, side faces of the semiconductor chip and side faces of the cover body as well as a top face of the cover body which faces away from the semiconductor chip being covered by the molding compound. In particular, it is possible for the semiconductor chip and the cover body to be fully covered on their side faces with the molding compound, which may be in direct contact with the aforementioned constituent parts there. Furthermore, the top face of the cover body, which faces away from the semiconductor chip, may also be fully covered with the molding compound.

According to at least one embodiment, the method comprises a method step in which the molding compound is partially or fully cured in order to form a molded body and the mold is removed.

The partial or full curing of the molding compound may for example be carried out by heating and/or irradiation, for example with UV radiation, of the molding compound. The mold may in particular be at least partially removed after the partial or full curing, at least an upper side of the molded body being exposed after the removal of the mold.

According to at least one embodiment, the method comprises a method step in which the molded body is thinned by a jet/beam process, the molded body being removed from the top face of the cover body and, after the thinning, the molded body being flush, in particular within the scope of the production tolerance, with the top face of the cover body or the molded body protruding beyond the top face of the cover body. The molded body may here in particular be removed fully from the top face of the cover body. In other words, the top face is then free of material of the molded body. Alternatively, the top face may remain covered in the region of the edges of the molded body. Contrast edges may thereby be generated. The remaining top face is then free of the molded body.

The jet/beam process is, for example, carried out extensively with a fan nozzle here so that the molded body is thinned along a strip that is moved over the molded body.

After the thinning, the material of the molded body is fully removed from the top face of the cover body, so that this face is free of the molded body. The side faces of the cover body and the side faces of the semiconductor chip preferably remain fully covered with the molded body. On the top face of the cover body, the molded body may be flush with the top face or may protrude beyond the top face.

According to at least one embodiment of the method for producing an optoelectronic component, the method comprises the following steps:
introducing a semiconductor chip and a cover body on an upper side of the semiconductor chip into a mold,
enclosing the semiconductor chip and the cover body in the mold with a molding compound, side faces of the semiconductor chip and side faces of the cover body, as well as a top face of the cover body which faces away from the semiconductor chip, being covered by the molding compound
partially or fully curing the molding compound in order to form a molded body, and removing the mold,
thinning the molded body by a jet/beam process, the molded body being fully removed from the top face of the cover body, the molded body being flush with the top face or protruding beyond the latter after the thinning.

The method may, in particular, be carried out here in the order indicated.

The method described here is based inter alia on the following considerations.

An optoelectronic component in which side faces of a semiconductor chip and/or of a cover body are covered by a molded body may, for example, be produced by an FAM (film-assisted molding) process. For this purpose, sealing is carried out by means of a flat, plane-parallel sealing face in a mold, in which case a mold release film which is pressed against the cover body and the semiconductor chip may be arranged on a mold upper side, on the side of the mold which faces toward the semiconductor chip. The surface to be kept free, that is to say for example the top face of the cover body, is thereby pressed about 10 to 20 μm into the film so that there is a corresponding protrusion of the cover body beyond the surrounding molded body in the finished optoelectronic component. This protrusion leads to emergence of light in particular on edges of the cover body, which may for example lead to an impaired contrast. Further, it is possible that damage may occur on the cover body and/or the semiconductor chip due to the pressing.

The present method is now based on the idea that emission on the edges of the cover body is prevented by the molded body being flush with the top face of the cover body or the molded body protruding beyond the top face, which results in improved optical properties, for example an improved contrast.

Further, in the method described here there is no direct contact between the mold and the top face of the cover body, so that direct mechanical contact of the mold with the component to be produced is obviated overall. No forces are therefore exerted on the constituent parts of the component to be produced, so that fractures and other damage can be avoided. It is therefore also possible to employ cover bodies that can be mechanically loaded little or not at all. In other words, in the present case the cover body is initially overmolded deliberately on its top face. The material thereby applied is subsequently removed by a jet/beam process, so that in total, for example, a flat component geometry in which edges of the cover body are not exposed may be produced.

According to at least one embodiment of the method, the jet/beam process comprises at least one of the following methods: sandblasting, wet blasting, bead blasting, CO2 blasting, laser caving, laser deflashing. With these methods, it is possible to thin the molded body particularly gently and uniformly, without damage to the top face of the cover body occurring.

According to at least one embodiment of the method, the mold comprises a projection on the top face of the cover body, the molded body having a cavity in the region of the projection after the removal of the mold. The projection may, for example, be configured trapezoidally in cross section and taper in the direction toward the top face of the cover body.

Because of the projection, the thickness of the molded body over the top face is reduced so that relatively little material of the molded body needs to be removed there in order to expose the top face. The thinning of the molded body in order to remove the molded body over the top layer may therefore be carried out particularly economically since the material can be removed rapidly. After the removal of the mold and before the thinning of the molded body, the molded body comprises a cavity over the top face in the region of the projection, this cavity being delimited by the molded body on the top face and, for example, obliquely extending side faces of the molded body.

According to at least one embodiment of the method, the projection has an extent in a lateral direction on its side that faces toward the top face which corresponds to an edge length of the semiconductor chip and/or of the cover body. In particular, the projection may have a plane closure face on its side that faces toward the top face, which corresponds in shape and size to the top face of the cover body. In this way, the projection can fully overlap the cover body and a thin layer of the molded body is deliberately generated over the cover body.

According to at least one embodiment of the method, the molded body protrudes beyond the top face after the thinning, so that the cavity which is generated by the projection is preserved in places. In this way, the molded body has an opening over the top face of the cover body, which opening may for example be delimited by obliquely extending side faces of the molded body. On the bottom face of the cavity, the top face of the cover body is exposed. It is thereby possible, for example, to absorb and/or reflect radiation which emerges laterally during the operation of the component, so that a contrast may be further increased.

According to at least one embodiment of the method, two or more semiconductor chips, respectively with a cover body on the upper side of each semiconductor chip, are introduced into the mold. In other words, the method is carried out for a multiplicity of semiconductor chips. The semiconductor chips and the associated cover bodies are for example configured identically here, so that a multiplicity of identical optoelectronic components may be produced.

According to at least one embodiment of the method, each cover body is assigned a projection. In other words, the mold has a projection as described here over each cover body, which projection may be adapted to keep a thickness of the molded body over the cover body small so that relatively little material of the molded body needs to be removed over the cover body during the subsequent thinning.

According to at least one embodiment of the method, the molded body is roughened by the jet/beam process. In other words, not only is the molded body thinned by the jet/beam process, but the surface of the molded body is also rougher on the faces of the molded body that are treated by the jet/beam process than on faces of the molded body that are not roughened. For example, the optical properties of the molded body may be modified by the roughening. For example, the roughened regions of the molded body appear more matte than unroughened regions of the molded body.

An optoelectronic component is further provided. The optoelectronic component may, in particular, be produced with the method described here. In other words, all features disclosed for the method are also disclosed for the component, and vice versa.

According to one embodiment, the component comprises a semiconductor chip and a cover body on an upper side of the semiconductor chip. The component further comprises a molded body, which laterally surrounds the semiconductor chip and the cover body. The molded body may here be flush with the cover body on the top face of the latter, or the molded body protrudes beyond the top face of the cover body, the molded body being roughened on its upper side. The roughening of the molded body results in particular from the jet/beam process described here, and is characteristic of the latter, so that the roughening is formed by tracks of the jet/beam process.

According to at least one embodiment, the molded body comprises a matrix material and filler particles, the proportion of the filler particles with respect to the molded body being 80 percent by weight or more. The matrix material is, for example, a radiation-transmissive plastic material such as silicone and/or epoxy resin. The filler particles are, for example, radiation-refracting and/or radiation-reflecting particles. Further, the filler particles may impart an increased mechanical stability to the molded body and improve the thermal properties of the molded body. For example, the molded body comprises filler particles which are formed with titanium dioxide and filler particles which are formed with silicon dioxide.

According to at least one embodiment, the filler particles are exposed in places on the upper side of the molded body. By the jet/beam process, it is possible that more relatively soft matrix material is removed than relatively hard filler particles. It is therefore possible that in places, the filler particles are not covered by the matrix material and are exposed on the surface of the molded body where the jet/beam process has been carried out. This modifies the optical properties of the molded body on its upper side.

According to at least one embodiment of the optoelectronic component or of the method, the molded body is configured to reflect radiation. The reflection of radiation may, in particular, be achieved by the filler particles. For example, the molded body may have a reflectivity of 70% or more for the electromagnetic radiation generated in the semiconductor chip.

According to at least one embodiment, the molded body protrudes beyond the top face of the cover body and the top face of the cover body is arranged in the cavity, which is delimited by oblique side faces of the molded body. The cavity is generated by the projection of the mold here, so that the profile of the side faces of the molded body, which laterally delimit the cavity, is also predefined. For example, the cavity widens upward away from the top face of the cover body. If the molded body is configured to reflect radiation, the top face may thus in particular be delimited by radiation-reflecting oblique side faces.

### BRIEF DESCRIPTION OF THE DRAWINGS

The method described here and the optoelectronic component described here will be explained in more detail with the aid of exemplary embodiments and the associated figures.

An embodiment for a method as described here and an optoelectronic component as described here is explained in more detail with the aid of the schematic sectional representations of FIGS. 1, 2 and 3.

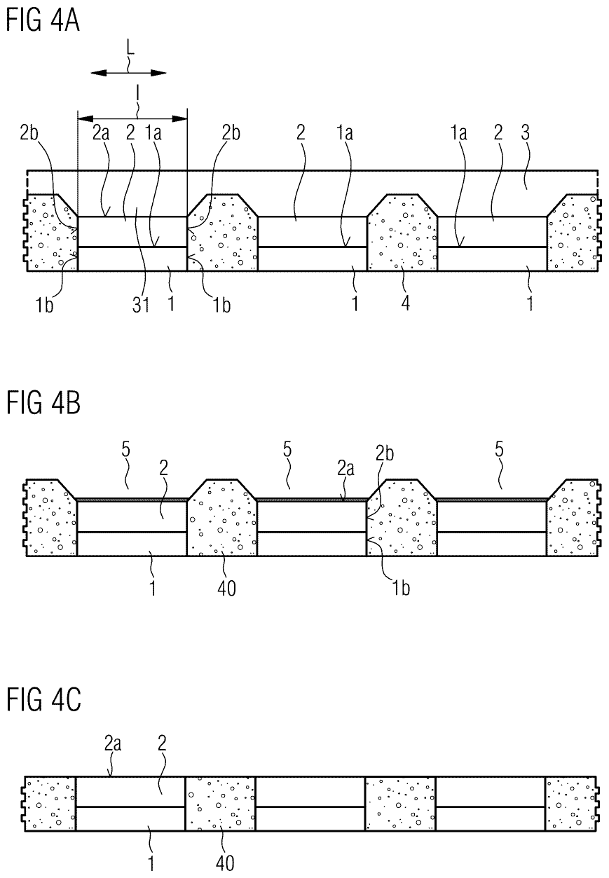

An exemplary embodiment of a method as described here is explained in more detail with the aid of the schematic sectional representations of FIGS. 4A, 4B, 4C.

An exemplary embodiment of an optoelectronic component as described here is explained in more detail with the aid of the schematic sectional representation of FIG. 5.

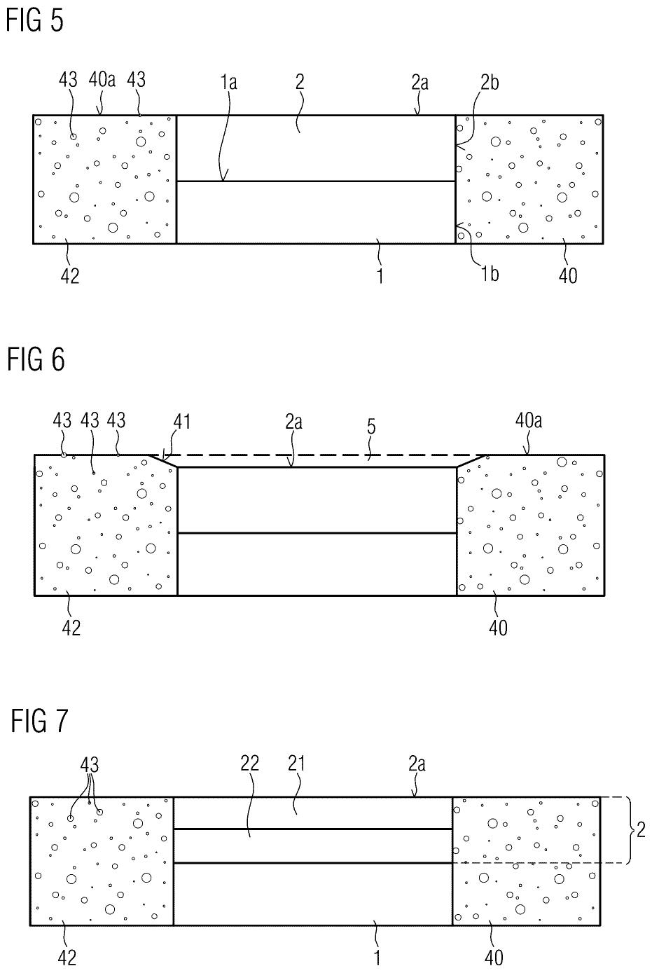

Further exemplary embodiments of an optoelectronic component as described here are explained in more detail with the aid of the schematic sectional representation of FIGS. 6 and 7.

In the figures, elements which are the same or of the same type, or which have the same effect, are provided with the same reference signs. The figures and the size proportions of the elements represented in the figures with respect to one another are not to be regarded as true to scale. Rather, individual elements may be represented exaggeratedly large for better representability and/or better clarity.

### DETAILED DESCRIPTION OF ILLUSTRATIVE EMBODIMENTS

FIG. 1 shows an optoelectronic component in a schematic sectional representation. The optoelectronic component comprises an optoelectronic semiconductor chip 1, which may for example be a light-emitting diode chip, and a cover body 2, which is mechanically fastened on an upper side 1a of the semiconductor chip 1.

The cover body 2 is, for example, a conversion element which is intended to convert at least a part of the electromagnetic radiation generated in the semiconductor chip 1 during operation into electromagnetic radiation, for example of a wavelength range with longer wavelengths than the radiation generated in the chip.

As shown in FIG. 1, in this optoelectronic component the side faces 2b of the cover body 2 protrude beyond a molded body 40 which otherwise fully surrounds the side faces 1b of the semiconductor chip 1 and the remaining side face 2b of the cover body 2. The molded body may, for example, be configured to absorb radiation and/or reflect radiation. Undesired emission 100 takes place through the exposed side faces 2b of the cover body 2, the effect of which is for example that a contrast is reduced.

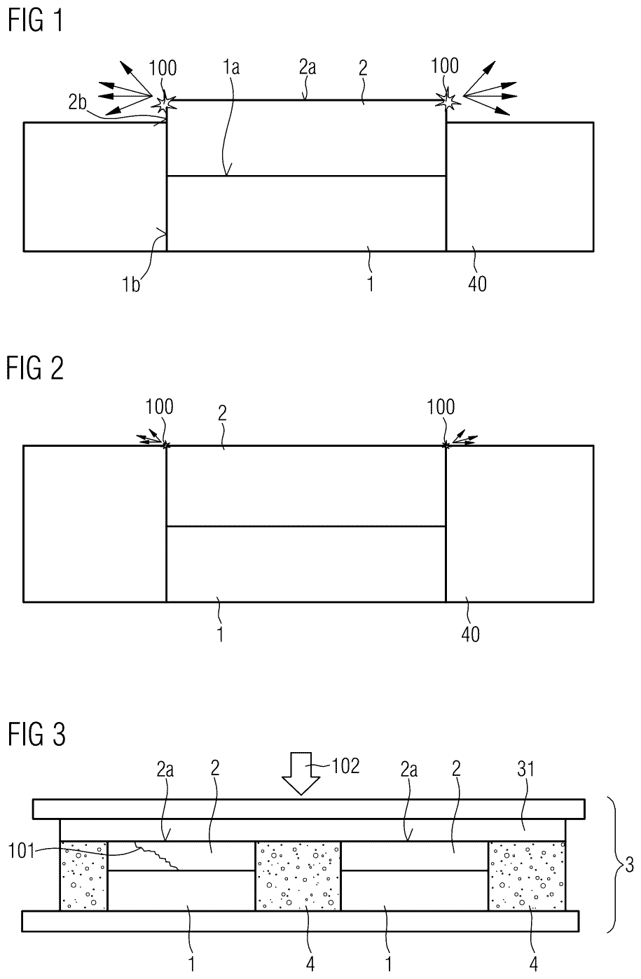

A similar optoelectronic component is shown in connection with the schematic sectional representation of FIG. 2, in which the protrusion of the cover body 2 beyond the molded body 40 is reduced but the problem still exists to a reduced extent.

The optoelectronic components shown in connection with FIGS. 1 and 2 may be produced as shown in connection with the schematic sectional representation of FIG. 3. In this case, optoelectronic semiconductor chips 1 with cover bodies 2 arranged thereon are introduced into a mold 3 in such a way that the top face 2a of each cover body 2 is covered with a release film 31. In other words, the top faces 2a are the cover faces during the shaping process and are exposed by removing the film 31 after the completion of the shaping.

The film 31 reinforces the sealing in order to protect the top faces 2a from wetting with a molding compound 4. During the shaping, for the sealing, the film 31 is pressed onto the top face 2a with a mechanical force 102 while being locally compressed. The part of the film 31 laterally next to the semiconductor chips 1 is compressed less strongly. Consequently, the molding compound 4 with which this region is filled lies laterally below the top face 2a after the removal of the mold 3, as shown in FIGS. 1 and 2, since the film 31 is thicker in this region than over the top faces 2a.

The problem may be reduced by a stronger force 102, which may for example lead to a component as described in connection with FIG. 2. However, this increases the risk of defects 101, for example cracks, which may occur in a mechanically delicate cover body 2, which comprises for example glass, due to the exerted force 102.

An exemplary embodiment of a method as described here is explained in more detail in connection with the schematic sectional representations of FIGS. 4A to 4C.

As represented in FIG. 4A, in the method, semiconductor chips 1 with cover bodies 2 arranged thereon, each of which is fastened on an upper side 1a of the semiconductor chip 1, are initially introduced into a mold 3.

The cover body 2 may be a cover body which is or comprises at least one of the following elements: optical element, glass platelet, optical diffuser, conversion element.

The mold 3 has a projection 32 on its side that faces toward the top face 2a of the cover body 2. On its side that faces toward the top face 2a, the projection 32 has an extent in a lateral direction L which corresponds to an edge length 1 of the semiconductor chip 1 and/or of the cover body 2. For example, the cover body 2 has the same shape and size in the lateral directions L on its bottom face which faces away from the top face 2a as the semiconductor chip 1 has on its upper side 1a. For example, the semiconductor chip 1 and the cover body 2 are each configured the shape of a cuboid. In this case, the projection 32 has a plane area on its side that faces toward the cover body 2 which has the same shape and size in the lateral directions L as the top face 2a of the cover body 2.

After the introduction of the semiconductor chips 2 with cover bodies 2 into the mold 3, the semiconductor chips 1 and the cover bodies 2 in the mold 3 are enclosed with a molding compound 4, side faces 1b of the semiconductor chip 1 and side faces 2b of the cover body 2, as well as a top face 2a of the cover body 2 which faces away from the semiconductor chip 1, being covered by the molding compound 4. Because of the projection 32, only a thin layer of the molding compound 4 is arranged over the cover body 2 on the top face 2a.

Overall, this results in the arrangement schematically represented in FIG. 4A.

In a next method step, FIG. 4B, the molding compound 4 is partially or fully cured in order to form a molded body 40 and the mold 3 is removed.

As may be seen in FIG. 4B, a cavity 5 is formed in the region of the projection 32 after the mold 4 is removed. The cavity 5 is delimited with material of the fully or partially cured molded body 40. The shape is predefined by the shape of the projection 32. The cover body 2 is covered on its top face 2a with a thin layer of the material of the molded body 40.

In a next method step, FIG. 4C, the molded body 40 is thinned by a jet/beam process, the molded body 40 being fully removed from the top face 2a of the cover body 2. In other words, after the thinning, the cover body 2 is fully exposed on its top face 2a. After the thinning, as shown in FIG. 4C, the molded body 40 is flush within the scope of the production tolerance with the top face 2a or the molded body 40 protrudes beyond the top face 2a.

“Within the scope of the production tolerance” means in particular that a deviation of +/−10 μm from being flush is possible. Here, in particular, manufacturing tolerances of the tool, process capability of the cleaning/ablation process and the height variations of the components are superimposed.

The jet/beam process here comprises at least one of the following methods: sandblasting, wet blasting, bead blasting, CO2 blasting, laser caving, laser deflashing.

In the described method, the semiconductor chip 1 is thus overmolded with the cover body 2 arranged thereon. However, the overmolding takes place by means of a structured mold which comprises the projection 32. In this way, during the downstream cleaning process, the thinning of the molded body 40, as little material as possible needs to be removed from the top face 2a of the cover body 2. For example, flat component surfaces with minimally exposed side edges of the cover body 2 are formed. Further, a relatively large force does not need to be exerted in order to achieve a flat component surface, as in the example of FIG. 3, so that mechanically delicate constituent parts such as mechanically delicate semiconductor chips 1 and mechanically delicate cover bodies 2 may be employed. Because of the plane component surface which can be produced, the use of a pick-and-place process in the further processing of the component is simplified.

As may be seen from FIGS. 4A to 4C, two or more semiconductor chips 1 with cover bodies 2 arranged thereon may be enclosed simultaneously during the method. In particular, each cover body may be assigned precisely one projection of the mold 3.

A first exemplary embodiment of an optoelectronic element as described here is described in more detail in connection with the schematic sectional representation of FIG. 5. The optoelectronic component comprises the semiconductor chip 1 and the cover body 2 on the upper side 1a of the semiconductor chip 1. The optoelectronic component further comprises a molded body 40, which laterally surrounds the semiconductor chip 1 and the cover body 2. For example, the molded body 40 is in direct contact with the semiconductor body of the semiconductor chip 1 on the side face 1b of the semiconductor chip 1. In the same way, the cover body may be in direct contact on its side face 2b with the molded body 40.

In the exemplary embodiment of FIG. 5, the molded body 40 and the cover body 2 are flush with one another on the top face 2a of the latter. Furthermore, the molded body 40 is roughened on its upper side 40a. The roughening may, for example, result from the jet/beam process previously carried out. It is possible here for the molded body 40 to comprise matrix material 42, into which filler particles 43 are introduced. For example, the matrix material is a radiation-transmissive plastic material, for example silicone and/or epoxy resin. The filler particles may, for example, be formed with titanium dioxide and/or silicon dioxide. A proportion by weight of the filler particles 43 with respect to the molded body 40 may be 80% or more. For example, the molded body 40 is configured to reflect radiation.

By the jet/beam process, it is possible for the matrix material 42 to be ablated more uniformly than the filler particles 43 by the jet/beam process. Filler particles 43 which impart a roughness to the surface 40a may thereby be exposed on the upper side 40a of the molded body 40. Furthermore, it is possible for the molded body 40 to appear optically matte on its upper side 40a because of the roughening.

A further exemplary embodiment of an optoelectronic component as described here is explained in more detail in connection with the schematic sectional representation of FIG. 6. In contrast to the exemplary embodiment of FIG. 5, the protrusion of the molded body 40 is not fully ablated in this exemplary embodiment, so that the molded body 40 protrudes beyond the top face 2a of the cover body 2 and the top face 2a of the cover body 2 is arranged in the cavity 5, which is delimited by oblique side faces 41 of the molded body 40. In this case, a part of the molded body 40 thus remains downstream of the top face 2a in the emission direction. This region of the molded body 40 may, for example, be employed for beamforming of the emerging light. Further, it constitutes mechanical protection for the cover body 2 owing to the protrusion. Because of the production method and the jet/beam process used therein, it is also possible for the side face 41 of the molded body 40 to be roughened.

A further exemplary embodiment of an optoelectronic component as described here is explained in more detail in connection with FIG. 7. In this exemplary embodiment, on its side that faces away from the semiconductor chip 1, the cover body 2 comprises a carrier 21 on which a converter 22 is applied on its side that faces toward the semiconductor chip 1. The carrier 21 may, for example, be a platelet of a radiation-transmissive material, for example glass. The carrier 21 may be mechanically delicately configured here without being damaged during the production of the optoelectronic component, since the particularly gentle production method described here is employed. It is possible here that the cover body 2 is flush on its top face 2a with the molded body 40, as represented in FIG. 7. It is however also possible, as represented for example in connection with FIG. 6, that the molded body 40 protrudes beyond the cover body 2 on its top face 2a and the top face 2a is arranged inside a cavity 5.

The description with the aid of the exemplary embodiments does not restrict the invention thereto. Rather, the invention comprises any new feature and any combination of features, which in particular includes any combination of features in the patent claims, even if this feature or this combination is not itself explicitly specified in the patent claims or exemplary embodiments.

1.-16. (canceled)

17. A method for producing an optoelectronic component, the method comprising:
introducing a semiconductor chip and a cover body, arranged on an upper side of the semiconductor chip, into a mold;
enclosing the semiconductor chip and the cover body in the mold with a molding compound, wherein side faces of the semiconductor chip, side faces of the cover body, and a top face of the cover body, which faces away from the semiconductor chip, are covered by the molding compound;
at least partially curing the molding compound in order to form a molded body;
removing the mold; and
thinning the molded body by a jet/beam process,
wherein the molded body is removed from the top face of the cover body, the molded body being flush with the top face or protruding beyond the latter after thinning,
wherein the mold has a projection on the top face of the cover body, and
wherein the molded body has a cavity in a region of the projection after removing the mold.

18. The method of claim 17, wherein the jet/beam process comprises at least one of the following methods: sandblasting, wet blasting, bead blasting, CO2 blasting, laser caving, or laser deflashing.

19. The method of claim 17, wherein the projection has an extent in a lateral direction on a side that faces toward the top face, which corresponds to an edge length of the semiconductor chip and/or of the cover body.

20. The method of claim 17, wherein the molded body protrudes beyond the top face after thinning so that the cavity is preserved in places.

21. The method of claim 17, wherein two or more semiconductor chips, each with a cover body on the upper side, are introduced into the mold.

22. The method of claim 21, wherein each cover body is assigned a projection.

23. The method of claim 17, wherein the molded body is roughened by the jet/beam process.

24. The method of claim 17, wherein the molded body comprises a matrix material and filler particles, and wherein a proportion of the filler particles with respect to the molded body is 80 percent by weight or more.

25. The method of claim 24, wherein the filler particles are exposed in places on the upper side of the molded body.

26. The method of claim 17, wherein the molded body is able to reflect radiation.

27. An optoelectronic component comprising:
a semiconductor chip and a cover body arranged on an upper side of the semiconductor chip; and
a molded body laterally surrounding the semiconductor chip and the cover body,
wherein the molded body is flush with the cover body on a top face of the cover body or the molded body protrudes beyond the top face of the cover body, and
wherein the molded body is rough on its upper side.

28. The optoelectronic component of claim 27, wherein the molded body comprises a matrix material and filler particles, and wherein a proportion of the filler particles with respect to the molded body is 80 percent by weight or more.

29. The optoelectronic component of claim 28, wherein the filler particles are exposed in places on the upper side of the molded body.

30. The optoelectronic component of claim 27, wherein the molded body is configured to reflect radiation.

31. The optoelectronic component of claim 27, wherein the molded body protrudes beyond the top face of the cover body and the top face of the cover body is arranged in a cavity, which is delimited by oblique side faces of the molded body.

32. The optoelectronic component of claim 31, wherein the side faces are rough.

33. The optoelectronic component of claim 27, wherein the cover body includes an optical element, a glass platelet, an optical diffuser, or a conversion element.

34. The optoelectronic component of claim 27, wherein, on a side that faces away from the semiconductor chip, the cover body comprises a carrier on which a converter is arranged on a side that faces toward the semiconductor chip.
